(19) United States
(12) Patent Application Publication
(10) Pub. No.: US 2007/0243713 A1
(43) Pub. Date: Oct. 18, 2007

(54) Apparatus and method for generating activated hydrogen for plasma stripping

(75) Inventor: Robert Charatan, Portland, OR (US)

Correspondence Address: WOMBLE CARLYLE SANDRIDGE & RICE, PLLC, ATTN: PATENT DOCKETING 32ND FLOOR, P.O. BOX 7037, ATLANTA, GA, 30357-0037, US

(73) Assignee: Lam Research Corporation, Fremont, CA (US)

(21) Appl. No.: 11/402,601

(22) Filed: Apr. 12, 2006

(51) Int. Cl. H01L 21/461; H01L 21/302

(52) U.S. Cl. 438/706; 438/709; 438/726; 438/727; 438/732

(57) ABSTRACT

A microwave source is used to create activated hydrogen in its ground state. An electron gun is used to boost the activated hydrogen into a metastable state by electron bombardment. The metastable activated hydrogen may then be used in a plasma etch to remove residue from a low k material.

### FIELD OF THE INVENTION

The present invention relates to a method for enhancing plasma stripping, such as is performed during semiconductor wafer processing. More particularly, it relates to a method for enhancing the plasma strip of a low-k dielectric.

### BACKGROUND OF THE INVENTION

During a standard plasma etch processing sequence, one masks the dielectric material to be etched with a sacrificial layer, etches the dielectric material in those areas not protected by the mask, and then removes the residue remaining from the mask and caused by the etch process.

Historically, in most cases, the dielectric material is some form of SiO₂. If a plasma residue removal (“strip”) process is used, the activated gas is primarily oxygen. Oxygen based plasmas are beneficial for stripping dielectric post etch residues when the etched material is SiO₂—the oxidizing plasma removes residue at high rates and does not damage the dielectric.

In recent years, for more advanced integration schemes, it has been found to be beneficial to replace the SiO₂ with a lower dielectric constant material (“low k” material). For the purposes of the present application, we will define a “low k” dielectric material to be one with a dielectric constant less than the dielectric constant of silicon dioxide, k<4. Since most low k materials contain carbon, the use of an oxygen strip plasma is often problematic. This is because an oxidizing plasma usually will react with carbon within the low k material, thereby damaging the film and consequently modifying the film's k value.

As an alternative to an oxidizing plasma, it is possible to strip the residue with a reducing plasma. Reducing plasmas using hydrogen gas are well known in the prior art. U.S. Pat. No. 6,235,453, for example, discloses forming a plasma with a gas substantially free of oxygen (e.g. an activated hydrogen gas) to remove photoresist from a low k dielectric layer.

As is known to those skilled in the art, plasma processing may be performed by using microwave frequency radiation to activate the gas. In the case of hydrogen based plasma stripping, the microwave radiation causes the hydrogen molecules to disassociate into more reactive species, which are then used to perform the removal by a reducing process, of byproducts from the etching process. To improve uniformity of the reactive species in the vicinity of the material being etched, a baffling system may be incorporated. However, since hydrogen surface recombination rates are high, the baffling system can have the deleterious effect of lowering the amount of activated hydrogen available for stripping.

In addition, the microwave source providing the radiation to create a plasma from the low pressure hydrogen may be remote from the material being stripped. This remoteness, which is sometimes a consequence of a design consideration, while beneficial for controlling the active species flux at the wafer surface and the wafer temperature will minimize the number of activated species present for stripping.

Due to the remoteness of the microwave source, and the baffling system used to improve uniformity of the reactive species, the amount and intensity of reactive species available during the stripping process may be somewhat limited.

### SUMMARY OF THE INVENTION

Generally speaking the present invention is directed to boosting the amount of activated hydrogen used in stripping residue from a low k material.

In one aspect, the present invention is directed to a method of enhancing the stripping performance of an activated species within a plasma in a processing chamber having a microwave source associated therewith. The method comprises providing an electron source, creating a plasma with the microwave source, the plasma comprising at least one activated species, and introducing electrons into the plasma to thereby boost at least some of the at least one activated species from a first atomic energy state to a second atomic energy state.

In another aspect, the present invention is directed to a method of enhancing the stripping performance of a hydrogen plasma in a processing chamber having a microwave source associated therewith. The method comprises creating a hydrogen plasma by means of the microwave source, and introducing an electron beam into the hydrogen plasma to thereby cause at least some unactivated hydrogen in said hydrogen plasma to become activated.

In still another aspect, the present invention is directed to a wafer processing apparatus comprising a reaction chamber, a microwave source configured to form a plasma within the reaction chamber, the plasma having at least one activated species, and an electron source configured to boost at least some of the at least one activated species from a first atomic energy state to a second atomic energy state.

In yet another aspect, the present invention is directed to a wafer processing apparatus comprising a reaction chamber, a microwave source configured to form a hydrogen plasma within the reaction chamber; and an electron source configured to cause at least some unactivated hydrogen in said hydrogen plasma to become activated.

### BRIEF DESCRIPTION OF THE DRAWINGS

The present invention is described with respect to one or more preferred embodiments using a number of figures in which:

FIG. 1 illustrates a system in accordance with the present invention that is capable of performing a plasma strip on a low k dielectric material using activated hydrogen.

FIG. 2 illustrates the principal steps in a prior art system for performing plasma strip on a low k dielectric material.

FIG. 3 illustrates the principal steps in accordance with the present invention for performing plasma strip on a low k dielectric material using activated hydrogen.

### DETAILED DESCRIPTION OF PREFERRED EMBODIMENT

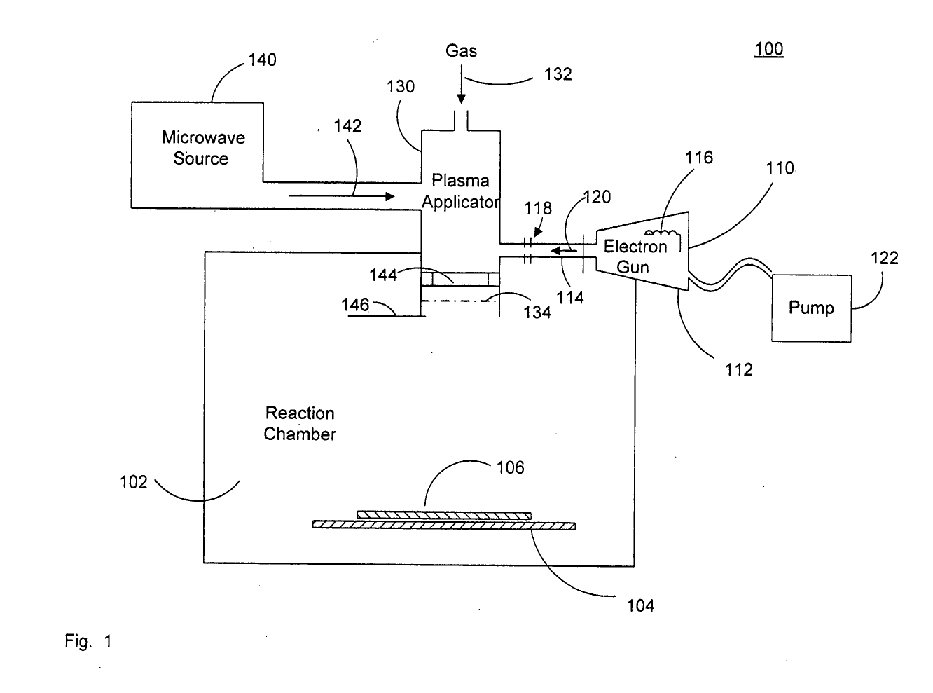

FIG. 1 shows a low-k etch system 100 in accordance with the present invention. The system 100 includes a reaction chamber 102, a plasma applicator 130, and a microwave source 140. In addition to these standard components, the system of the present invention includes an electron gun 112, discussed further below. It is understood that various connections, motors, controllers and the like have been omitted for clarity.

The reaction chamber 102 has a support 104 therein. The support 104 may be a chuck, a platen or other platform on which wafers may be placed, mounted, retained etc. In FIG. 1, a wafer 106 is shown to be placed on the support 104. It is understood that in the context of the present invention, the wafer 106 is to be subjected to an activated gas for the purpose of stripping post etch residue.

The microwave source 104 is used to generate microwave energy 142 which subsequently generates a plasma within the plasma applicator 130. In the application described herein, hydrogen gas 132 is introduced into the plasma applicator 130 in a manner known to those skilled in the art, and the microwave energy added there to create the plasma. This plasma is then introduced into the reaction chamber via a passageway 134 comprising one or more apertures, such as in the form of a showerhead. A plasma flow controller device, such as a baffle 144, or a shutter 146, or both, may be used to control the flow of plasma into the reaction chamber 102.

In one embodiment, shown in FIG. 1, the electron beam 120 is introduced at a point between the microwave source 104 and the plasma flow control device 144, which may be a gas baffling system. One potential benefit of introducing the electron beam 120 between the microwave source 104 and the plasma flow control device 144, but prior to where the gas enters the reaction chamber 102, is that potential interactions between the wafer 106 and the electron beam 110 are reduced.

In another embodiment (not shown), the electron beam is introduced after the plasma flow control device, at a point closer to the wafer to be stripped. Such a configuration could provide the benefit of a creating a plasma in the vicinity of the wafer 106 that contains an increased proportion of activated gas.

In the present invention, the amount of activated gas and/or the energy state of at least some activated hydrogen within the plasma is boosted by an electron source 110. The electron source can be of a number of standard types, but will generally comprise an electron gun 110 and associated electronics to generate an electrode beam 120. As seen in FIG. 1, the electron gun 100 includes a cathode 112, an anode 114, a filament 116 and power supplies (not shown), all of which together are instrumental in accelerating and steering the electrode beam. Additionally, to optimize the beam dimensions, a series of collimators 118 may be employed.

In one embodiment, a Kaufman-style electron gun is employed, although other types may be used as well.

In one embodiment, the electron gun 110 operates at a pressure of about a few mTorr while the microwave source generates a plasma, which is subsequently controlled at a pressure within the reaction chamber of between 300 mTorr and 2 Torr. The pressure within the plasma applicator 130 is slightly higher than the pressure within the reaction chamber. To allow the electron gun to operate at its nominal pressure and help mitigate this difference, a differential pumping system, 122, may be employed.

A typical processing condition for a hydrogen microwave stripping plasma is 2500 W of microwave power/5000 SCCM HeH₂ gas/550 mT. Helium serves the dual purpose of acting as a carrier gas and minimizing pyrophoric related risks associated with the use of pure hydrogen. Within such a pressure regime, a differential pumping system can be beneficial to ensure optimal performance of the electron gun.

To increase the amount of activated hydrogen, in one embodiment, the electron gun 110 provides a supply 120 of high energy electrons into the plasma applicator 130, where they interact with the plasma and increase the amount of activated hydrogen therein. The supply of high energy electrons may be in the form of an electron beam 120. One or more aligned orifices, shown generally as 118, may be used to better collimate the electron beam. In an alternate embodiment, the electron gun provides its supply of electrons directly into the reaction chamber 102 where the boosting takes place.

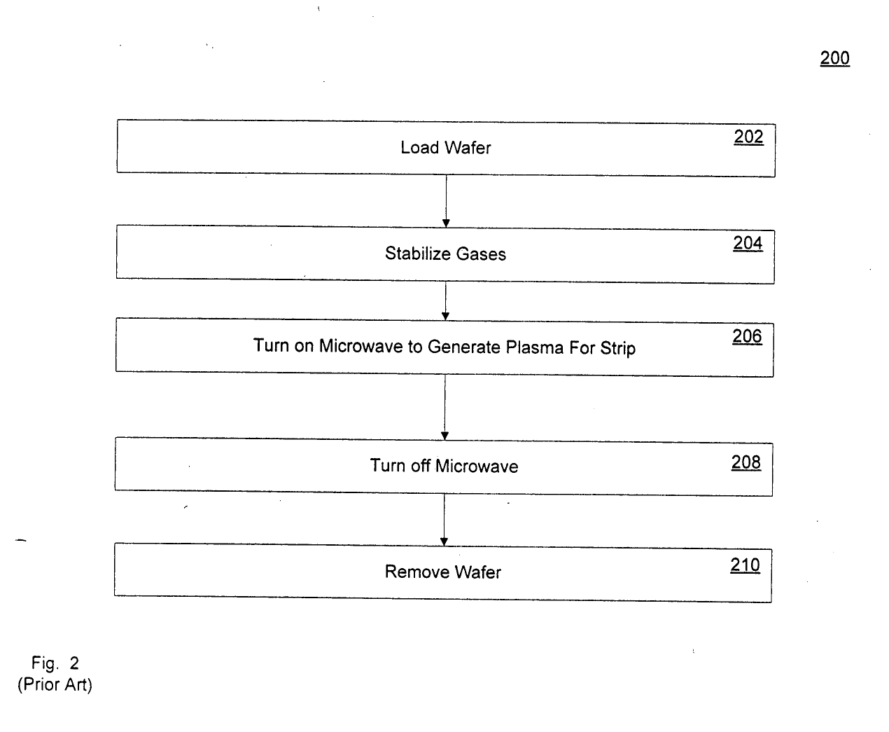

FIG. 2 shows a simplified prior art method 200 for performing a low-k dielectric strip on a wafer, in the absence of an electron gun to boost the amount of activated hydrogen within the plasma. In step 202, the wafer is loaded into the reaction chamber and in step 204, the gases are introduced and their flow rates are stabilized, all in a known manner. Next, in step 206, the microwave source is used to generate the plasma for stripping. After the strip process is completed in step 208, the microwave source is turned off to stop creation of plasma, and the chamber is evacuated. Finally, in step 210, the wafer is removed.

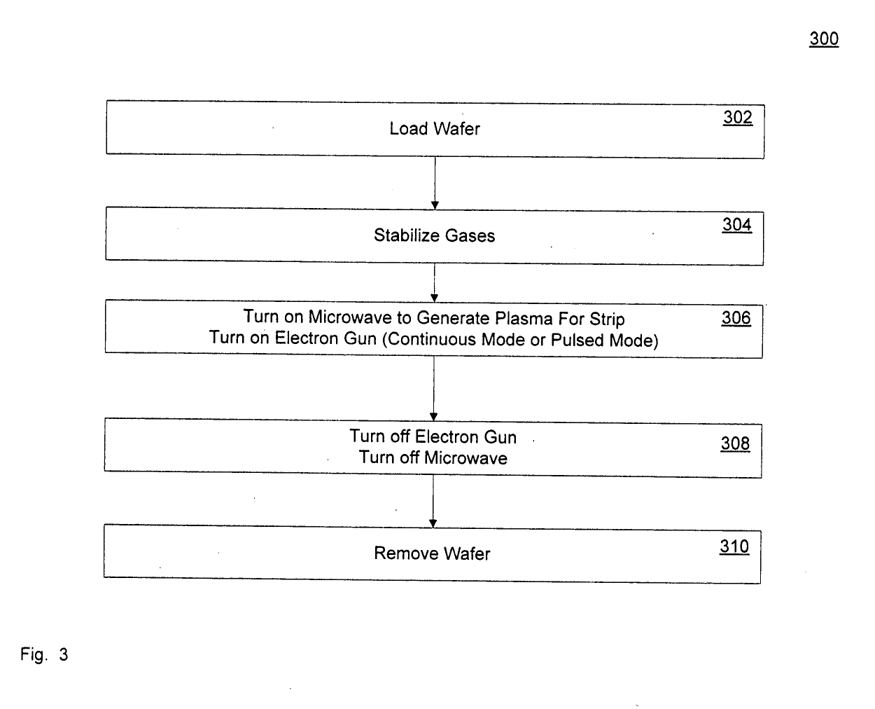

FIG. 3 shows a simplified method 300 for performing a low-k dielectric strip on a wafer in the presence of an electron gun to boost the amount of activated hydrogen within the plasma. In step 302, the wafer is loaded into the reaction chamber and in step 304, the gases are introduced and their flow rates are stabilized, all as before. Next, in step 306, two things are done. First, the microwave source 140 is turned to generate the plasma for etching and second, the electron gun 110 is turned on to boost the energy state of the hydrogen ions. At the conclusion of the strip process, in step 308, the electron gun 110 and the microwave source 140 are both turned off and the chamber is evacuated. Finally, in step 310, the wafer is removed from the chamber.

In one embodiment, in step 306, the microwave source 140 is turned on first, and only then is the electron gun 110 turned on. Detectors may be used to determine when the electron gun 110 should be turned on, after the microwave source 140 has been activated. Then in step 308, the electron gun 110 is turned off first, and only then is the plasma source 140 turned off. In another embodiment, both the electron gun 110 and the microwave source 140 are turned on at the same time, and turned off at the same time. In still another embodiment, the electron gun 110 is the first to be turned on, and also the first to be turned off. And in yet other embodiments, one or the other of the electron gun 110 and the microwave source 140 is the first to be turned on and also the first to be turned off.

It is further understood that the electron gun 110 need not be on at all times during the entire stripping process.

In one embodiment, to prolong the life of the filament, the electron gun 110 may only be selectively activated during certain key steps of a stripping process that has numerous steps. For example, the electron gun may be turned on for fewer than 20% of all steps conducted during the stripping process.

In another embodiment, the electron gun 110 is turned on for no more than a predetermined percentage of time that the microwave source 140 is turned on. For example, the electron gun may only be turned on for, say, 25% of the time that the microwave source is turned on, and so has a 25% duty cycle relative to the microwave source.

And when it is turned on, the electron gun 110 may be used in either a continuous mode or in a pulsed mode, as needed. In one embodiment, the electron gun is pulsed wherein the pulse timing is on the order of between 100 ms and 10 s. The electron gun's duty cycle may be such that it is on for less than 30% of the time, even while it is pulsing.

Furthermore, the shutter 146 may be used to selectively open and close the apertures during any of the foregoing situations.

Although the present invention has been described to a certain degree of particularity, it should be understood that various alterations and modifications could be made without departing from the scope of the invention as hereinafter claimed. For instance, while in the foregoing discussion, only one electron source is connected to the chamber, there can be instances where it would be beneficial to couple two or multiple electron sources to the processing chamber. Also, instead of an activated hydrogen gas, and electron gun may be used to boost the amount of activated species even when the gas is not hydrogen.

What is claimed is:

1. A method of enhancing the stripping performance of an activated species within a plasma in a processing chamber having a microwave source associated therewith, the method comprising:
providing an electron source;
creating a plasma with the microwave source, the plasma comprising at least one activated species;
introducing electrons into the plasma to thereby boost at least some of the at least one activated species from a first atomic energy state to a second atomic energy state.

2. The method according to claim 1, wherein the at least one activated species comprises hydrogen.

3. The method according to claim 1, wherein the second atomic energy state is a metastable state.

4. The method according to claim 1, wherein said step of introducing comprises operating an electron gun.

5. The method according to claim 1, wherein said step of introducing comprises operating an electron gun to create said electrons.

6. The method according to claim 5, comprising pulsing the electron gun.

7. The method according to claim 5, comprising operating the electron gun at a predetermined duty cycle.

8. The method according to claim 5, comprising operating the electron gun only during a plurality of predetermined steps.

9. The method according to claim 1, comprising introducing electrons into the plasma prior to gas baffling.

10. The method according to claim 1, comprising introducing electrons into the plasma after gas baffling.

11. A method of enhancing the stripping performance of a hydrogen plasma in a processing chamber having a microwave source associated therewith, the method comprising:
creating a hydrogen plasma by means of the microwave source;
introducing an electron beam into the hydrogen plasma to thereby cause at least some unactivated hydrogen in said hydrogen plasma to become activated.

12. A wafer processing apparatus comprising:
a reaction chamber;
a microwave source configured to form a plasma within the reaction chamber, the plasma having at least one activated species; and
an electron source configured to boost at least some of the at least one activated species from a first atomic energy state to a second atomic energy state.

13. The apparatus according to claim 12, wherein the at least one activated species comprises hydrogen.

14. The apparatus according to claim 12, wherein the first atomic energy state is a ground state and the second atomic energy state is a metastable state.

15. The apparatus according to claim 12, wherein the electron source is an electron gun.

16. A wafer processing apparatus comprising:
a reaction chamber;
a microwave source configured to form a hydrogen plasma within the reaction chamber; and
an electron source configured to cause at least some unactivated hydrogen in said hydrogen plasma to become activated.

17. The apparatus according to claim 16, wherein the electron source is an electron gun.
